(19) United States
(12) Patent Application Publication
(10) Pub. No.: US 2026/0255677 A1
(43) Pub. Date: Aug. 27, 2026

(54) DISPLAY PANEL, DISPLAY DEVICE

(71) Applicants: Beijing BOE Display Technology Co., Ltd., Beijing (CN); BOE Technology Group Co., Ltd., Beijing (CN)

(72) Inventors: Lingdan BO, Beijing (CN); Jianhua HUANG, Beijing (CN); Yingying QU, Beijing (CN); Chongyang ZHAO, Beijing (CN); Qiujie SU, Beijing (CN); Xue ZHENG, Beijing (CN); Yingmeng MIAO, Beijing (CN); Wenjie HOU, Beijing (CN); Yue YANG, Beijing (CN)

(21) Appl. No.: 18/881,973

(22) PCT Filed: Apr. 17, 2024
(86) PCT No.: PCT/CN2024/088143

§ 371 Date: Jan. 7, 2025

(30) Foreign Application Priority Data
May 31, 2023 (CN) 202310636006.7

(51) Int. Cl. H10D 86/40; G02F 1/1362; G02F 1/1368; H10D 86/60

(52) U.S. Cl. CPC H10D 86/441; G02F 1/136209; G02F 1/136286; G02F 1/1368; H10D 86/60

(57) ABSTRACT

The present disclosure provides a display panel and a display device. The display panel includes a first substrate, a plurality of gate lines on the first substrate, a plurality of sub-pixels arranged in an array, each of the plurality of sub-pixels having a length along a first direction and a width along a second direction, the length of each sub-pixel being greater than the width of each sub-pixel, the first direction being the same as the extending direction of the gate line, and the second direction intersecting with the first direction, and a light shielding layer on a side of the plurality of gate lines away from the first substrate and including a first part along the first direction and a second part along the second direction, a width of the first part along the second direction being less than a width of the second part along the first direction.

### RELATED APPLICATION

This application claims the benefit of Chinese Patent Application No. 202310636006.7 filed on May 31, 2023, the entire disclosure of which is incorporated herein by reference.

### TECHNICAL FIELD

The present disclosure relates to the field of display technology, in particular to a display panel and a display device including the display panel.

### BACKGROUND

With the continuous development of display technology, users have put forward higher and higher requirements for the contrast, brightness and stability of a display device. The liquid crystal display device has been widely used because of light weight, good shock resistance, wide viewing angle and high contrast.

### SUMMARY

According to an aspect of the present disclosure, a display panel is provided, which comprises: a first substrate; a plurality of gate lines on the first substrate and extending along a first direction; a plurality of sub-pixels arranged in an array, each of the plurality of sub-pixels having a length along the first direction and a width along a second direction, the length of each sub-pixel being greater than the width of each sub-pixel, the second direction intersecting with the first direction; and a light shielding layer on a side of the plurality of gate lines away from the first substrate and comprising a first part along the first direction and a second part along the second direction. A width of the first part along the second direction is less than a width of the second part along the first direction.

In some embodiments, a ratio of the width to the length of each sub-pixel is 1:3.

In some embodiments, the display panel further comprises: a plurality of common leads on the first substrate and extending along the first direction; and a plurality of data lines on the first substrate and extending along the second direction, the plurality of data lines and the plurality of gate lines intersecting with each other to enclose the plurality of sub-pixels. Each gate line is adjacent to a common lead, a gate line and a common lead that are adjacent are between two adjacent rows of sub-pixels, and orthographic projections of the gate line and the common lead that are adjacent on the first substrate fall within an orthographic projection of the first part of the light shielding layer on the first substrate.

In some embodiments, two edges of the gate line extending along the first direction comprise a first edge and a second edge, two edges of the first part of the light shielding layer extending along the first direction comprise a third edge and a fourth edge, the first edge is farther away from the common lead adjacent to the gate line than the second edge, and the first edge is closer to the third edge than the second edge. A distance between an orthographic projection of the first edge on the first substrate and an orthographic projection of the third edge on the first substrate is a first distance, a distance between an orthographic projection of the second edge on the first substrate and an orthographic projection of the fourth edge on the first substrate is a second distance, the first distance is equal or unequal to the second distance.

In some embodiments, the first distance and the second distance are both 6~15 μm.

In some embodiments, the first distance is 8.5 μm.

In some embodiments, two edges of the common lead extending along the first direction comprise a fifth edge and a sixth edge, the sixth edge is closer to the fourth edge than the fifth edge, a distance between an orthographic projection of the sixth edge on the first substrate and the orthographic projection of the fourth edge on the first substrate is a third distance, the third distance is less than the first distance and the second distance.

In some embodiments, the third distance is 2~4 μm.

In some embodiments, an orthographic projection of each of the plurality of data lines on the first substrate falls within an orthographic projection of the second part of the light shielding layer on the first substrate, and a distance between an orthographic projection of two edges extending along the second direction of each data line on the first substrate and an orthographic projection of two edges extending along the second direction of the second part of the light shielding layer on the first substrate is 13~30 μm.

In some embodiments, the display panel further comprises a plurality of pixel electrodes arranged in an array on the first substrate. Each sub-pixel is provided with one of the plurality of pixel electrodes, each pixel electrode comprises a first side and a second side extending along the first direction and opposite to each other, an orthographic projection of the first side on the first substrate is between an orthographic projection of the common lead on the first substrate and an orthographic projection of the gate line adjacent to the common lead on the first substrate.

In some embodiments, a distance between the orthographic projection of the first side of the pixel electrode on the first substrate and the orthographic projection of the second edge of the gate line on the first substrate is a fourth distance, the fourth distance is less than or equal to the first distance and the second distance.

In some embodiments, the fourth distance is 4~6 μm.

In some embodiments, the display panel further comprises a plurality of thin film transistors on the first substrate, each sub-pixel comprising at least one of the plurality of thin film transistors. A gate electrode of a thin film transistor of each sub-pixel is electrically connected with the gate line, a first electrode of the thin film transistor of each sub-pixel is electrically connected with the pixel electrode of the sub-pixel, a second electrode of the thin film transistor of each sub-pixel is electrically connected with the data line, and the second electrodes of the thin film transistors of two adjacent sub-pixels in a same column of sub-pixels are electrically connected with different data lines respectively.

In some embodiments, the display panel further comprises a plurality of common electrodes arranged in an array on the first substrate, each sub-pixel is provided with one of the plurality of common electrodes, each common electrode comprises a third side and a fourth side extending along the first direction and opposite to each other, two adjacent common electrodes in the second direction are at two sides of a same gate line, a distance between an orthographic projection of the third side of one of the two adjacent common electrodes on the first substrate and the orthographic projection of the first edge of the same gate line on the first substrate is a fifth distance, a distance between an orthographic projection of the fourth side of the other of the two adjacent common electrodes on the first substrate and the orthographic projection of the second edge of the same gate line on the first substrate is a sixth distance, both the fifth distance and the sixth distance are greater than or equal to the fourth distance.

In some embodiments, each of the fifth distance and the sixth distance is 6~8 μm.

In some embodiments, the display panel further comprises a liquid crystal layer. The common electrode and the pixel electrode are on a same side of the liquid crystal layer, and materials of the common electrode and the pixel electrode comprise indium tin oxide.

In some embodiments, the common electrode is multiplexed as a touch electrode in a touch stage.

In some embodiments, the display panel further comprises: a second substrate opposite to the first substrate; a photo spacer between the first substrate and the second substrate. Each of the plurality of data lines comprises a body part and a widening part, a width of the widening part along the first direction is greater than a width of the body part along the first direction, and an orthographic projection of the photo spacer on the first substrate falls within an orthographic projection of the widening part on the first substrate.

In some embodiments, the display panel further comprises: a plurality of common electrodes on the first substrate, each sub-pixel comprising one of the plurality of common electrodes, and the common electrodes in a same row of sub-pixels being connected to a same common lead; and a connecting line through which the common electrodes of two adjacent sub-pixels in a same column of sub-pixels are electrically connected to each other. In a thickness direction of the first substrate, the connecting line partially overlaps with the gate line and the common lead to form a first overlapping structure, the gate line partially overlaps with the data line to form a second overlapping structure, the common lead partially overlaps with the data line to form a third overlapping structure, and a thin film transistor electrically connected with the gate line partially overlaps with the gate line to form a fourth overlapping structure. Orthographic projections of the first overlapping structure, the second overlapping structure, the third overlapping structure and the fourth overlapping structure on the first substrate surround the orthographic projection of the photo spacer on the first substrate.

In some embodiments, the display panel further comprises a color filter on a side of the second substrate facing the first substrate. The color filter comprises a plurality of sub-color filters arranged in a plurality of rows along the first direction and in a plurality of columns along the second direction, and there is no gap between any two adjacent sub-color filters in a same column of sub-color filters.

In some embodiments, each sub-color filter comprises a seventh edge and an eighth edge extending along the first direction and opposite to each other, the eighth edge of each sub-color filter is in direct contact with the seventh edge of another sub-color filter adjacent in the second direction, and the eighth edge comprises at least one protrusion.

In some embodiments, the photo spacer is at a side of the color filter away from the second substrate, and the protrusion is configured to accommodate a bottom of the photo spacer.

According to another aspect of the present disclosure, a display panel is provided, which comprises: a first substrate; a plurality of gate lines on the first substrate and extending along a first direction; a plurality of common leads on the first substrate and extending along the first direction; and a light shielding layer on a side of the plurality of gate lines away from the first substrate and comprising a first part along the first direction. Any one of the plurality of gate lines and any one of the plurality of common leads are adjacent to each other, and orthographic projections of a gate line and a common lead that ate adjacent on the first substrate fall within an orthographic projection of the first part of the light shielding layer on the first substrate, and two edges of the gate line extending along the first direction comprise a first edge and a second edge, two edges of the first part of the light shielding layer extending along the first direction comprise a third edge and a fourth edge, the first edge is farther away from the common lead adjacent to the gate line than the second edge, and the first edge is closer to the third edge than the second edge, a distance between an orthographic projection of the first edge on the first substrate and an orthographic projection of the third edge on the first substrate is a first distance, a distance between an orthographic projection of the second edge on the first substrate and an orthographic projection of the fourth edge on the first substrate is a second distance, the first distance is equal or unequal to the second distance.

In some embodiments, the first distance and the second distance are both 6~15 μm.

In some embodiments, two edges of the common lead extending along the first direction comprise a fifth edge and a sixth edge, the sixth edge is closer to the fourth edge than the fifth edge, a distance between an orthographic projection of the sixth edge on the first substrate and the orthographic projection of the fourth edge on the first substrate is a third distance, the third distance is less than the first distance and the second distance.

In some embodiments, the third distance is 2~4 μm.

In some embodiments, the display panel further comprises a plurality of data lines on the first substrate and extending along a second direction, the second direction intersecting with the first direction. The light shielding layer further comprises a second part along the second direction, an orthographic projection of each of the plurality of data lines on the first substrate falls within an orthographic projection of the second part of the light shielding layer on the first substrate, and a distance between an orthographic projection of two edges extending along the second direction of each data line on the first substrate and an orthographic projection of two edges extending along the second direction of the second part of the light shielding layer on the first substrate is 13~30 μm.

In some embodiments, the display panel further comprises a plurality of sub-pixels arranged in an array, each of the plurality of sub-pixels has a length along the first direction and a width along the second direction, the length of each sub-pixel is greater than the width of each sub-pixel, and a width of the first part of the light shielding layer along the second direction is less than a width of the second part of the light shielding layer along the first direction.

According to yet another aspect of the present disclosure, a display device comprising the display panel described in any of the previous embodiments is provided.

### BRIEF DESCRIPTION OF THE DRAWINGS

In order to describe the technical solutions in the embodiments of the present disclosure more clearly, the drawings needed to be used in the embodiments will be briefly introduced below. Obviously, the drawings in the following description are only some embodiments of the present disclosure. Those of ordinary skill in the art can also obtain other drawings based on these drawings without undue experimentation.

FIG. 1 shows a top view of a partial structure of a display panel according to an embodiment of the present disclosure;

FIG. 2 shows a schematic sectional view taken along the line AA′ of FIG. 1;

FIG. 3 shows a schematic sectional view taken along the line BB′ of FIG. 1;

FIG. 4 shows a simulation graph of the change of light leakage distance of the display panel with the distance between the pixel electrode and the gate according to an embodiment of the present disclosure;

FIG. 5 shows a simulation graph of the change of light leakage distance of the display panel with the distance between the common electrode and the gate according to an embodiment of the present disclosure;

FIG. 6 shows a pixel structure of a conventional display panel;

FIG. 7 shows a pixel structure of a display panel according to an embodiment of the present disclosure;

FIG. 8 shows a schematic illustration of a color filter of a conventional display panel;

FIG. 9 shows a schematic illustration of a color filter of a display panel according to an embodiment of the present disclosure;

FIG. 10 shows a picture of a scanning electron microscope at a color filter of a conventional display panel;

FIG. 11 shows a picture of a scanning electron microscope at a color filter of a display panel according to an embodiment of the present disclosure;

FIG. 12 shows a schematic sectional view of a partial structure of a display panel according to an embodiment of the present disclosure;

FIG. 13 shows a schematic sectional view of a partial structure of a display panel according to an embodiment of the present disclosure;

FIG. 14 shows a structural diagram of a display panel in different preparation stages according to an embodiment of the present disclosure; and

FIG. 15 shows a block diagram of a display device according to an embodiment of the present disclosure.

### DETAILED DESCRIPTION OF THE DISCLOSURE

The technical solutions in the embodiments of the present disclosure will be clearly described below with reference to the accompanying drawings. Obviously, the described embodiments are only some, but not all, of the embodiments of the present disclosure. Based on the embodiments of the present disclosure, all other embodiments obtained by those of ordinary skill in the art without undue experimentation fall within the scope of protection of this disclosure.

With the continuous development of display technology, users put forward higher and higher requirements for the brightness and contrast of the display panel to meet the demand of watching the display pictures with higher quality. An important factor affecting the brightness of the display panel is the aperture ratio, and an important factor affecting the contrast is whether there is light leakage in the display panel. The term “aperture ratio” refers to the ratio of the area of the effective region through which light can pass in each sub-pixel of the display panel to the total area of the sub-pixel. Due to various technological and design reasons, the brightness and contrast of the current display panel still need to be further improved.

In view of this, embodiments of the present disclosure provide a display panel and a display device including the display panel, which can achieve at least one of improved aperture ratio and improved contrast. Higher aperture ratio can make the display panel and display device have higher brightness, and at the same time help to reduce the brightness of the backlight to save power consumption. The optimized structural design can make the display panel and display device better block the light leakage, thus having better contrast and improving the picture quality.

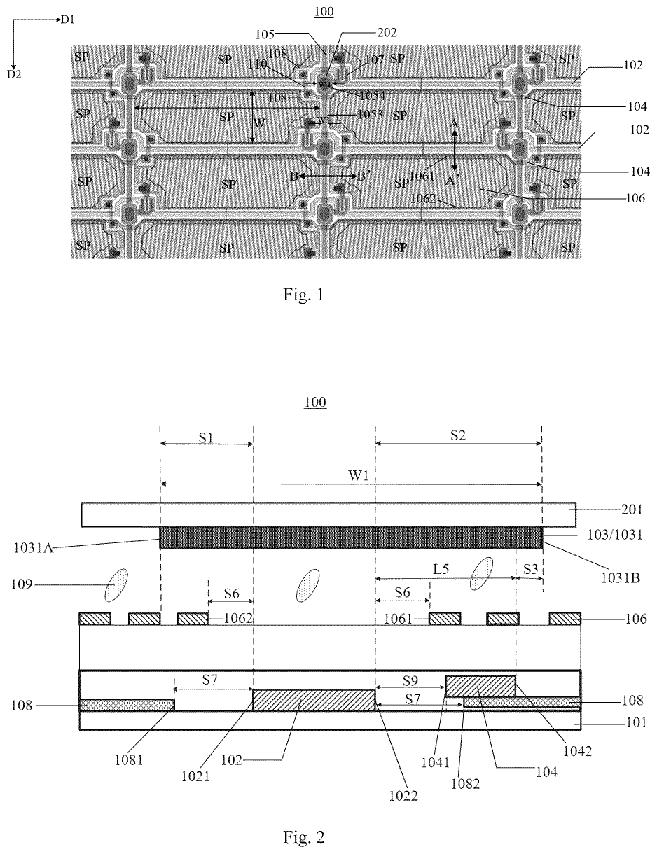

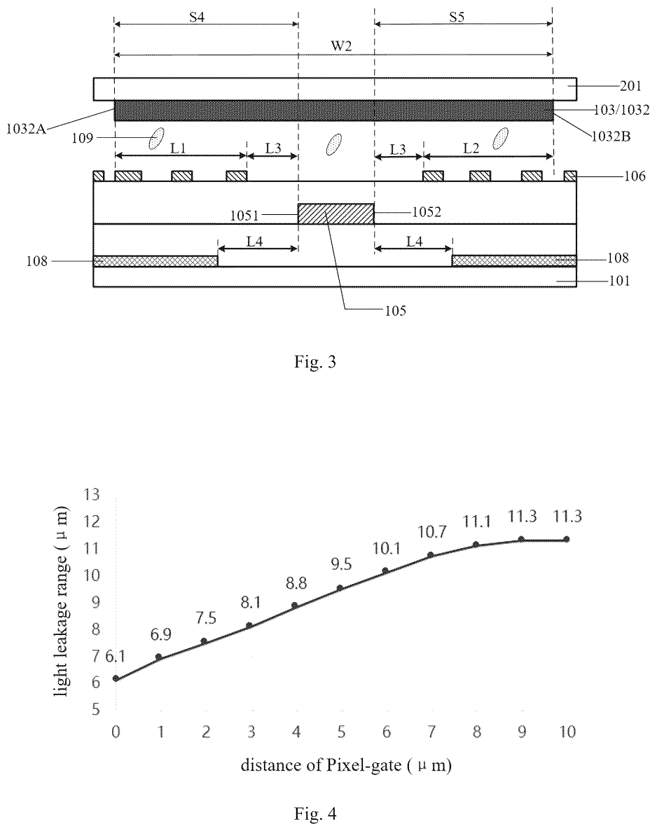

FIG. 1 shows a schematic plan view of a partial structure of a display panel 100 according to an embodiment of the present disclosure, FIG. 2 shows a schematic cross-sectional view taken along the line AA′ in FIG. 1, and FIG. 3 shows a schematic cross-sectional view taken along the line BB′ in FIG. 1. Referring to FIGS. 1 to 3, the display panel 100 includes: a first substrate 101; a plurality of gate lines 102 arranged on the first substrate 101 and extending in a first direction D1; a plurality of sub-pixels SP arranged in an array, each sub-pixel SP having a length L along the first direction D1 and a width W along a second direction D2, the length L of each sub-pixel SP being greater than the width W of each sub-pixel SP, and the second direction D2 intersecting with the first direction D1, for example, the second direction D2 being perpendicular to the first direction D1; and a light shielding layer 103 on a side of the gate line 102 away from the first substrate 101 and comprising a first part 1031 along the first direction D1 and a second part 1032 along the second direction D2, the width of the first part 1031 along the second direction D2 being W1, the width of the second part 1032 along the first direction D1 being W2, W1 being less than W2.

The light shielding layer 103 is used to shield some components of the display panel 100, such as signal lines, thin film transistors, storage capacitors, etc., so as to prevent the light at the corresponding positions of these components from exiting at the light emitting side of the display panel 100 uncontrollably, which would otherwise affect the normal display of the display panel 100. The width of the light shielding layer 103 affects the aperture ratio of the display panel 100. The light shielding layer 103 may be, for example, a black matrix (BM). In a conventional display panel, the length of a sub-pixel in the first direction D1 is usually smaller than the width in the second direction D2. Compared with the conventional display panel, the arrangement direction of the sub-pixel SP of the display panel 100 provided by the embodiments of the present disclosure is rotated, the length L of each sub-pixel SP along the first direction D1 is greater than the width W along the second direction D2. The first part 1031 of the light shielding layer 103 is arranged along the first direction D1 (i.e., the first part 1031 is arranged along the long side direction of the sub-pixel SP), and the second part 1032 of the light shielding layer 103 is arranged along the second direction D2 (i.e., the second part 1032 is arranged along the short side direction of the sub-pixel SP). Therefore, for each sub-pixel SP, the area occupied by the first part 1031 of the light shielding layer 103 is larger than the area occupied by the second part 1032, so that the width W1 of the first part 1031 has a greater influence on the aperture ratio of the sub-pixel SP. In the display panel 100, by making the width W1 of the first part 1031 of the light shielding layer 103 less than the width W2 of the second part 1032, the width W1 of the first part 1031 can be minimized on the premise of shielding the light leakage, so as to maximize the aperture ratio of the sub-pixel SP and promote the brightness improvement of the display panel 100. In some embodiments, the width W1 of the first part 1031 of the light shielding layer 103 is 30.5 μm, and the width W2 of the second part 1032 of the light shielding layer 103 is 57 μm.

In some embodiments, the ratio of the width W along the second direction D2 to the length L along the first direction D1 of each sub-pixel SP of the display panel 100 is 1:3. The ratio of the width along the second direction D2 to the length along the first direction D1 of each sub-pixel of a conventional display panel is usually 3:1. Under the condition that the total length along the first direction D1 and the total width along the second direction D2 of the display panel are unchanged, the number of sub-pixels SP of the display panel 100 arranged in the first direction D1 is ⅓ of that of the conventional display panel, and the number of sub-pixels SP of the display panel 100 arranged in the second direction D2 is 3 times that of the conventional display panel. The number of gate lines is usually positively correlated with the number of rows of sub-pixels SP (the row direction is the same as the first direction D1) and the number of data lines is usually positively correlated with the number of columns of sub-pixels SP (the column direction is the same as the second direction D2). Therefore, the number of gate lines of the display panel 100 is three times that of the conventional display panel, but the number of data lines of the display panel 100 is one third of that of the conventional display panel. The conventional display panel may be called Single Gate display panel, and the display panel 100 may be called Triple Gate display panel. The number of COF (Source IC) is positively correlated to the number of data lines, since the number of data lines of the display panel 100 is reduced to ⅓ of that of the conventional Single Gate display panel, the required number of COFs of the display panel 100 is correspondingly reduced to ⅓ of that of the conventional Single Gate display panel, which greatly reduces the production cost. Taking the full high definition (FHD) display product as an example, the conventional Single Gate display panel needs 6 COFs, while the Triple Gate display panel only needs 2 COFs. Taking the ultra high definition (UHD) display products as an example, the conventional Single Gate display panel needs 12 COFs, while the Triple Gate display panel only needs 4 COFs. Therefore, the Triple Gate display panel can minimize the circuit cost of the display panel, especially the circuit cost of the large-size display panel (such as a television).

As shown in FIGS. 1 to 3, in some embodiments, the display panel 100 may further include a plurality of common leads 104 arranged on the first substrate 101 and extending in the first direction D1. Each gate line 102 is adjacent to a common lead 104, the gate line 102 and the common lead 104 that are adjacent are located between two adjacent rows of sub-pixels SP, and the orthographic projections of the gate line 102 and the common lead 104 that are adjacent on the first substrate 101 fall within the orthographic projection of the first part 1031 of the light shielding layer 103 on the first substrate. Because light leakage (especially the light leakage at the side view angle) is easy to occur near the gate line 102 and the common lead 104, by covering the gate line 102 and the common lead 104 with the first part 1031 of the light shielding layer 103, uncontrolled light can be prevented from emitting from the light emitting side of the display panel 100, so that the light leakage phenomenon of the display panel 100 can be avoided.

Further, referring to FIGS. 1 and 2, two edges of the gate line 102 extending in the first direction D1 include a first edge 1021 and a second edge 1022, and two edges of the first part 1031 of the light shielding layer 103 extending in the first direction D1 include a third edge 1031A and a fourth edge 1031B. The first edge 1021 of the gate line 102 is farther away from the common lead 104 adjacent to the gate line 102 than the second edge 1022, and the first edge 1021 of the gate line 102 is closer to the third edge 1031A of the first part 1031 of the light shielding layer 103 than the second edge 1022. In some embodiments, the distance between an orthographic projection of the first edge 1021 on the first substrate 101 and an orthographic projection of the third edge 1031A on the first substrate 101 is a first distance S1, and the distance between an orthographic projection of the second edge 1022 on the first substrate 101 and an orthographic projection of the fourth edge 1031B on the first substrate 101 is a second distance S2. S1 and S2 may be equal or not equal. In some embodiments, S1 is 6-15 μm, such as 6 μm, 7 μm, 8 μm, 9 μm, 10 μm, 11 μm, 12 μm, 13 μm, 14 μm, 15 μm, etc. In some embodiments, S1 is 6-11 μm. In some embodiments, S2 is 6-15 μm, such as 6 μm, 7 μm, 8 μm, 9 μm, 10 μm, 11 μm, 12 μm, 13 μm, 14 μm, 15 μm, etc. Near the gate line 102, especially near the first edge 1021 of the gate line 102, light leakage from the side view angle is easy to occur, and the light leakage distance is about 8~11 μm. By making the two edges 1031A and 1031B of the first part 1031 of the light shielding layer 103 extend beyond the two edges 1021 and 1022 of the gate line 102 by 6-15 μm, respectively, the light leakage region can be shielded, thereby avoiding the light leakage phenomenon from the side view angle.

In an example, S1 is 8.5 μm. As mentioned above, the width W1 of the first part 1031 has a significant influence on the aperture ratio of the sub-pixel SP, therefore, by making the third edge 1031A of the first part 1031 of the light shielding layer 103 extend beyond the first edge 1021 of the gate line 102 by about 8.5 μm, the width W1 of the first part 1031 is minimized on the premise that the light leakage from the side view angle at the gate line 102 can be shielded, so as to maximize the aperture ratio of the sub-pixel SP.

In some embodiments, as shown in FIG. 2, two edges of the common lead 104 extending in the first direction D1 include a fifth edge 1041 and a sixth edge 1042, the sixth edge 1042 is closer to the fourth edge 1031B of the first part 1031 of the light shielding layer 103 than the fifth edge 1041, and a distance between an orthographic projection of the sixth edge 1042 on the first substrate 101 and an orthographic projection of the fourth edge 1031B on the first substrate 101 is a third distance S3, which is less than S1 and S2. In some examples, S3 is 2-4 μm, such as 2 μm, 3 μm, 4 μm, etc. On the side of the common lead 104 far away from the adjacent gate line 102, there is a weak region of rubbing orientation (which is used to arrange the liquid crystal molecules according to rubbing orientation) where has poor anchoring of liquid crystal and is easy to cause light leakage from the side view angle. Generally, the range of the weak region of rubbing orientation is 2~4 μm. Therefore, by making the distance S3 that the first part 1031 of the light shielding layer 1031 extends beyond the common lead 104 be 2~4 μm, the risk of light leakage from the side view angle at the weak region of rubbing orientation can be reduced or even avoided. In an example, S3 is 3 μm, which can minimize the width W1 of the first part 1031 on the premise of avoiding light leakage from the side view angle, thus maximizing the aperture ratio of the sub-pixel SP.

As shown in FIG. 2, the distance between the second edge 1022 of the gate line 102 and the fifth edge 1041 of the common lead 104 adjacent thereto is S9. In some embodiments, S9 is about 6 μm, which can ensure that the gate line 102 and the common lead 104 on the same layer are not short-circuited during mass production. In some embodiments, the width of the gate line 102 is about 8 μm, and the width of the common lead 104 is about 5 μm. In some embodiments, the distance L5 between the orthographic projection of the second edge 1022 of the gate line 102 on the first substrate 101 and the orthographic projection of the sixth edge 1042 of the adjacent common lead 104 on the first substrate 101 is about 11 μm.

Referring to FIGS. 1 and 3, in some embodiments, the display panel 100 may further include a plurality of data lines 105, which are arranged on the first substrate 101 and extend in the second direction D2, and the plurality of data lines 105 and the plurality of gate lines 102 intersect with each other to enclose a plurality of sub-pixels SP. The orthographic projection of each data line 105 on the first substrate 101 falls within the orthographic projection of the second part 1032 of the light shielding layer 103 on the first substrate 101. Each data line 105 includes two edges 1051 and 1052 extending in the second direction D2, and the second part 1032 of the light shielding layer 103 includes two edges 1032A and 1032B extending in the second direction D2. The distance S4 between the orthographic projection of the edge 1051 of the data line 105 on the first substrate 101 and the orthographic projection of the edge 1032A of the second part 1032 of the light shielding layer 103 on the first substrate 101 is 13~30 μm, for example, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, etc. The distance S5 between the orthographic projection of the edge 1052 of the data line 105 on the first substrate 101 and the orthographic projection of the edge 1032B of the second part 1032 of the light shielding layer 103 on the first substrate 101 is 13~30 μm, for example, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, etc. Because the electric field between the data line 105 and the pixel electrode 106 causes the liquid crystal to rotate unexpectedly, the phenomenon of light leakage from side view angle is easy to occur near the data line 105. The second part 1032 of the light shielding layer 103 extends beyond two sides of the data line 105 by about 13~30 μm in the first direction D1, on one hand, it can shield the light leakage region (the width of the light leakage region is about 13 μm) to avoid light leakage from the side view angle, on the other hand, even if the array substrate and the counter substrate of the display panel 100 are misaligned (the alignment accuracy is about 6.5 μm) during assembly, the width W2 of the second part 1032 can ensure that there will be no light leakage due to the misalignment.

The width W1 of the first part 1031 of the light shielding layer 103 may cover the above-mentioned possible light leakage distance. In some embodiments, the width W1 of the first part 1031 of the light shielding layer 103 is 30.5 μm.

In some embodiments, the display panel 100 may further include a plurality of pixel electrodes 106 and a plurality of common electrodes 108 arranged in an array on the first substrate 101 as well as a liquid crystal layer 109 on the first substrate 101, each sub-pixel SP is provided with a pixel electrode 106 and a common electrode 108, and the pixel electrode 106 may be an electrode with slits. In some examples, the pixel electrode 106 is located on the side of the common electrode 108 away from the first substrate 101, and both are located on the same side of the liquid crystal layer 109 close to the first substrate 101, and the materials of the pixel electrode 106 and the common electrode 108 are indium tin oxide. In other words, the display panel 100 is a display panel based on advanced super dimension switch (ADS) technology. ADS technology can overcome the problem of low light transmission efficiency of conventional in-plane-switching (IPS) technology, has advantages such as higher light transmission efficiency, hard screen, ultra-wide viewing angle, ultra-high color expression, ultra-high speed moving picture processing, etc., and is more suitable for large-size display products.

As shown in FIG. 3, for each data line 105 and two columns of sub-pixels SP located on both sides of the data line 105, the distance between the orthographic projection of the pixel electrode 106 in each column among the two columns of sub-pixels SP on the first substrate 101 and the orthographic projection of the data line 105 on the first substrate 101 is L3, and the orthographic projection of the common electrode 108 in each column among the two columns of sub-pixels SP on the first substrate 101 and the orthographic projection of the data line 105 on the first substrate 101 is L4. In some embodiments, L3 may be 6 μm and L4 may be 7 μm. In a conventional display panel, the distance between the data line and the pixel electrode is generally 5-7 μm, and the distance between the data line and the common electrode is generally 3~5 μm. Compared with the conventional display panel, the distance L3 between the data line 105 and the pixel electrode 106 and the distance L4 between the data line 105 and the common electrode 108 of the display panel 100 are increased, because the capacitance C of the data line 105 of the Triple Gate product is large, increasing the distance can reduce the capacitance C of the data line 105, thus improving the charging rate of the product.

The distance between the orthographic projection of the edge close to the data line 105 of the pixel electrode 106 that is on the first side of the data line 105 (e.g. on the left side of the data line 105 in FIG. 3) on the first substrate 101 and the orthographic projection of the edge 1032A of the second part 1032 of the light shielding layer 103 on the first substrate 101 is L1, and the distance between the orthographic projection of the edge close to the data line 105 of the pixel electrode 106 that is on the second side of the data line 105 (e.g. on the right side of the data line 105 in FIG. 3) on the first substrate 101 and the orthographic projection of the edge 1032B of the second part 1032 of the light shielding layer 103 on the first substrate 101 is L2. L1 and L2 may be the same or different. In an example, L1 is 15 μm and L2 is 24 μm.

The width W2 of the second part 1032 of the light shielding layer 103 may cover the above-mentioned possible light leakage distance. In some embodiments, the width W2 of the second part 1032 of the light shielding layer 103 is 57 μm.

Referring to FIGS. 1 and 2, each pixel electrode 106 includes a first side 1061 and a second side 1062 extending in the first direction D1 and opposite to each other, the orthographic projection of the first side 1061 on the first substrate 101 is located between the orthographic projection of the common lead 104 on the first substrate 101 and the orthographic projection of the gate line 102 adjacent to the common lead 104 on the first substrate 101. The first side 1061 (i.e., the edge of the slit) of the pixel electrode 106 is between the common lead 104 and the gate line 102, which makes the pixel have better luminous efficacy and higher light transmittance. The material of the common lead 104 is usually an opaque material. By positioning the pixel electrode 106 partially between the gate line 102 and the adjacent common lead 104, the sixth edge 1042 of the common lead 104 can be basically flush with the edge of the light leakage region, so that the light leakage region can be blocked by the opaque common lead 104.

FIG. 4 shows a simulation graph of the light leakage range at the gate line 106 when the pixel electrode 106 is at different distances from the gate line 102 (in this case, the distance between the common electrode 108 and the gate line 102 is fixed at 7 μm). The distance between the pixel electrode 106 and the gate line 102 affects the light leakage distance from the side view angle of the display panel. Referring to FIG. 2, two adjacent pixel electrodes 106 in the second direction D2 are located on both sides of the same gate line 102, the distance between the orthographic projection of the first side 1061 of one of the two adjacent pixel electrodes 106 on the first substrate 101 and the orthographic projection of the second edge 1022 of the gate line 102 on the first substrate 101 is a fourth distance S6, and the distance between the orthographic projection of the second side 1062 of the other of the two adjacent pixel electrodes 106 on the first substrate 101 and the orthographic projection of the first edge 1021 of the gate line 102 on the first substrate 101 is also the fourth distance S6, where S6 is less than or equal to S1 and S2. As can be seen from FIG. 4, the smaller S6, the smaller the light leakage distance. When S6 is between 0~7 μm, the change of light leakage distance is obvious and basically linear. When S6 is greater than 7 μm, the light leakage distance tends to be stable gradually, which is caused by the gradual weakening of electric field. Although the smaller S6 is, the smaller the light leakage distance is, when S6 is too small (for example, S6 is 0~4 μm), the capacitance between the gate line 102 and the pixel electrode 106 is large and the voltage of the pixel electrode 106 is increased, which would increase the risk of flicker. In some embodiments, S6 is designed to be 4~6 μm, such as 4 μm, 5 μm, 6 μm, etc. The distance S6 between the pixel electrode 106 and the gate line 102 is 4~6 μm, which can realize the minimum light leakage distance under the premise of avoiding the risk of flicker, and can maximize the aperture ratio of the sub-pixel SP.

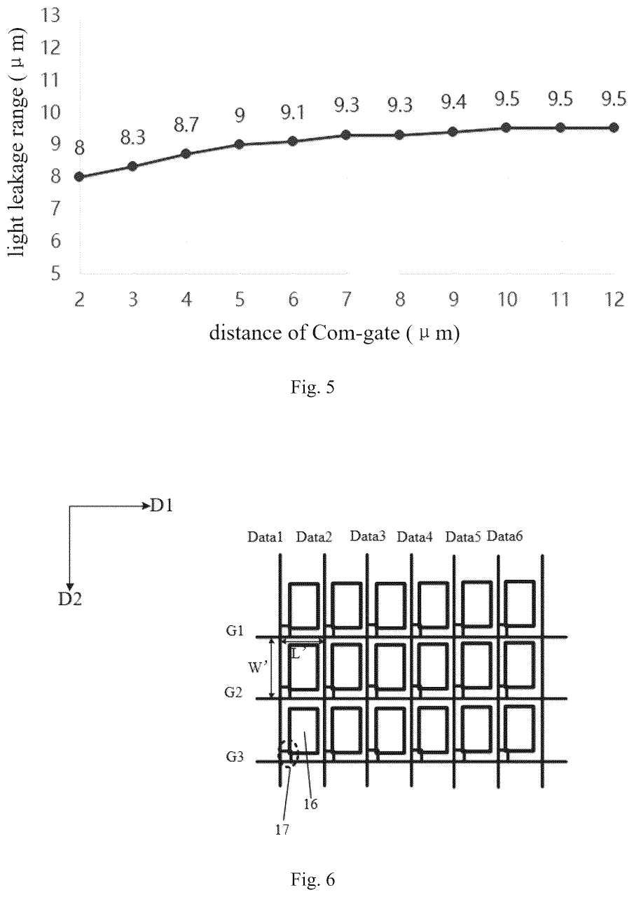

FIG. 5 shows a simulation graph of the light leakage range at the gate line 106 when the common electrode 108 is at different distances from the gate line 102 (in this case, the distance between the pixel electrode 106 and the gate line 102 is fixed at 5 μm). The distance between the common electrode 108 and the gate line 102 also affects the light leakage distance from the side view angle of the display panel, Referring to FIG. 2, each common electrode 108 includes a third side 1081 and a fourth side 1082 extending in the first direction D1 and opposite to each other, and two adjacent common electrodes 108 in the second direction D2 are located on both sides of the same gate line 102. The distance between the orthographic projection of the third side 1081 of one of the two adjacent common electrodes 108 on the first substrate 101 and the orthographic projection of the first edge 1021 of the gate line 102 on the first substrate 101 is a fifth distance S7, and the distance between the orthographic projection of the fourth side 1082 of the other of the two adjacent common electrodes 108 on the first substrate 101 and the orthographic projection of the second edge 1022 of the gate line 102 on the first substrate 101 is a sixth distance S7. The fifth distance and the sixth distance may be the same or different. In an example, the fifth distance is 7 μm and the sixth distance is 8 μm. It can be seen from FIG. 5 that the smaller S7 is, the smaller the light leakage distance is, but the degree of change is relatively small. For example, when S7 is between 2~12 μm, the light leakage distance is between 8~9.5 μm, especially when S7 is greater than 7 μm, the light leakage distance gradually tends to be stable. Therefore, the value of S7 may be designed to be 6~8 μm, for example, 6 μm, 7 μm, 8 μm, etc., which can avoid light leakage and short circuit caused by too close distance between the common electrode 108 and the gate line 102.

It should be pointed out that although it is explained here that different distances between the pixel electrode 106 and the gate line 102 affect the light leakage range, and different distances between the common electrode 108 and the gate line 102 also affect the light leakage range, as mentioned above, the width W1 of the first part 1031 and the width W2 of the second part 1032 of the light shielding layer 103 can shield the light leakage caused by the spacing between the pixel electrode 106 and the gate line 102 and the light leakage caused by the spacing between the common electrode 108 and the gate line 102 as well as the light leakage caused by other factors, so that the display panel 100 basically has no phenomenon of light leakage.

As shown in FIGS. 1 to 3, the display panel 100 may further include a second substrate 201 opposite to the first substrate 101, and a photo spacer (PS) 202 located between the first substrate 101 and the second substrate 201. The data line 105 includes a body part 1053 and a widening part 1054, the width W4 of the widening part 1054 in the first direction D1 is greater than the width W3 of the body part 1053 in the first direction D1, and the orthographic projection of the photo spacer 202 on the first substrate 101 falls within the orthographic projection of the widening part 1054 on the first substrate 101. Placing the photo spacer 202 here is beneficial to form a dam-like structure around it (see below), thus being beneficial to limit the sliding range of the photo spacer 202.

In some embodiments, the display panel 100 may further include a connecting line 110, through which the common electrodes 108 of two adjacent sub-pixels in the same column of sub-pixels are electrically connected to each other, and the common electrodes 108 in the same row of sub-pixels are connected to the same common lead 104, so that the common electrodes 108 in the display panel 100 are connected to each other, ensuring the voltage uniformity of the common electrodes 108. In some embodiments, the connecting line 110 is located on the same layer as the pixel electrode 106.

As shown in FIG. 1, in the thickness direction of the first substrate 101, the connecting line 110 partially overlaps with the gate line 102 and the common lead 104 to form a first overlapping structure, the gate line 102 partially overlaps with the data line 105 to form a second overlapping structure, the common lead 104 partially overlaps with the data line 105 to form a third overlapping structure, and the thin film transistor 107 partially overlaps with the gate line 102 to form a fourth overlapping structure. Orthographic projections of the first overlapping structure, the second overlapping structure, the third overlapping structure and the fourth overlapping structure on the first substrate 101 surround the orthographic projection of the photo spacer 202 on the first substrate 101. The first overlapping structure, the second overlapping structure, the third overlapping structure, and the fourth overlapping structure each have a certain thickness, so they surround the photo spacer 202 in a form similar to a dam, thereby preventing the photo spacer 202 from sliding and reducing the sliding range of the photo spacer 202. The light shielding layer 103 is also used to shield the photo spacer 202, because the sliding range of the photo spacer 202 is reduced, the width W1 of the first part 1031 and the width W2 of the second part 1032 of the light shielding layer 103 can also be reduced accordingly, which is beneficial to improving the aperture ratio of the sub-pixel SP of the display panel 100 and improving the brightness of the display panel 100.

The connecting line 110 and the thin film transistor 107 are oppositely arranged on both sides of the photo spacer 202. For example, as shown in FIG. 1, the connecting line 110 is arranged on the left side of the photo spacer 202, and correspondingly, the thin film transistor 107 is arranged on the right side of the photo spacer 202. Alternatively, the connecting line 110 is arranged on the right side of the photo spacer 202, and correspondingly, the thin film transistor 107 is arranged on the left side of the photo spacer 202. In some embodiments, the thickness of the connecting line 110 is about 40 nm, the gate line 102 and the common lead 104 are arranged in the same layer and both are about 445 nm, the connecting line 110 is arranged in the same layer as the pixel electrode 106 and located on the side of the gate line 102 and the common lead 104 away from the first substrate 101, so the thickness of the first overlapping structure is equal to the thickness of the connecting line 110 plus the thickness of the gate line 102 (or the common lead 104), and the overlapping thickness is approximately equal to 485 nm. The thickness of the data line 105 is about 375 nm, the data line 105 is located on the side of the gate line 102 and the common lead 104 away from the first substrate 101, so the thickness of the second overlapping structure is equal to the thickness of the data line 105 plus the thickness of the gate line 102, and the overlapping thickness is approximately equal to 820 nm. The thickness of the third overlapping structure is equal to the thickness of the data line 105 plus the thickness of the common lead 104, and the overlapping thickness is approximately equal to 820 nm. The thickness of the fourth overlapping structure is equal to the thickness of part of the thin film transistor 107 plus the thickness of the gate line 102. The thickness of the photo spacer 202 is about 3.6 μm. The first overlapping structure, the second overlapping structure, the third overlapping structure and the fourth overlapping structure surround the photo spacer 202 in the form of dams, so that the sliding range of the photo spacer 202 can be reduced.

In some embodiments, the display panel 100 may be a touch display panel. In this case, the common electrode 108 is time-multiplexed. In the display stage, the common electrode 108 is used as a common electrode to provide a common voltage. In the touch scanning stage, the common electrode 108 is used as a touch electrode, the touch electrode is electrically connected to the touch control circuit through a touch signal line. When touching, a touch object (for example, a human finger) touches the touch display device, the capacitance of the touch electrode at the touch point will change, the touch control circuit determines the touch position by detecting the change of the self-capacitance of the touch electrode.

FIG. 6 shows an illustration of a pixel structure of a conventional single gate display panel. As shown in FIG. 6, a plurality of data lines and a plurality of gate lines intersect with each other to enclose a plurality of sub-pixels, and the ratio of the length L′ in the first direction D1 to the width W′ in the second direction D2 of each sub-pixel is 1:3. Each sub-pixel includes a pixel electrode 16, which is connected to the corresponding data line and gate line via a thin film transistor 17. Specifically, the pixel electrodes 16 in the first row of sub-pixels are connected to the same gate line G1 via the thin film transistor 17, the pixel electrodes 16 in the second row of sub-pixels are connected to the same gate line G2 via the thin film transistor 17, and the pixel electrodes 16 in the third row of sub-pixels are connected to the same gate line G3 via the thin film transistor 17, the pixel electrodes 16 in the first column of sub-pixels are connected to the same data line Data1 via the thin film transistor 17, the pixel electrodes 16 in the second column of sub-pixels are connected to the same data line Data2 via the thin film transistor 17, the pixel electrodes 16 in the third column of sub-pixels are connected to the same data line Data3 via the thin film transistor 17, the pixel electrodes 16 in the fourth column of sub-pixels are connected to the same data line Data4 via the thin film transistor 17, the pixel electrodes 16 in the fifth column of sub-pixels are connected to the same data line Data5 via the thin film transistor 17, and the pixel electrodes 16 in the sixth column of sub-pixels are connected to the same data line Data6 via the thin film transistor 17. In other words, in a conventional display panel, the pixel electrodes 16 in the same column of sub-pixels are connected to the same data line via the thin film transistor 17, and this arrangement of the pixel structure is called a column architecture. Due to the uneven polarity distribution of sub-pixels caused by the difference of precharge voltage, vertical stripes usually occur when the display panel of column architecture displays, which affects the user's impression.

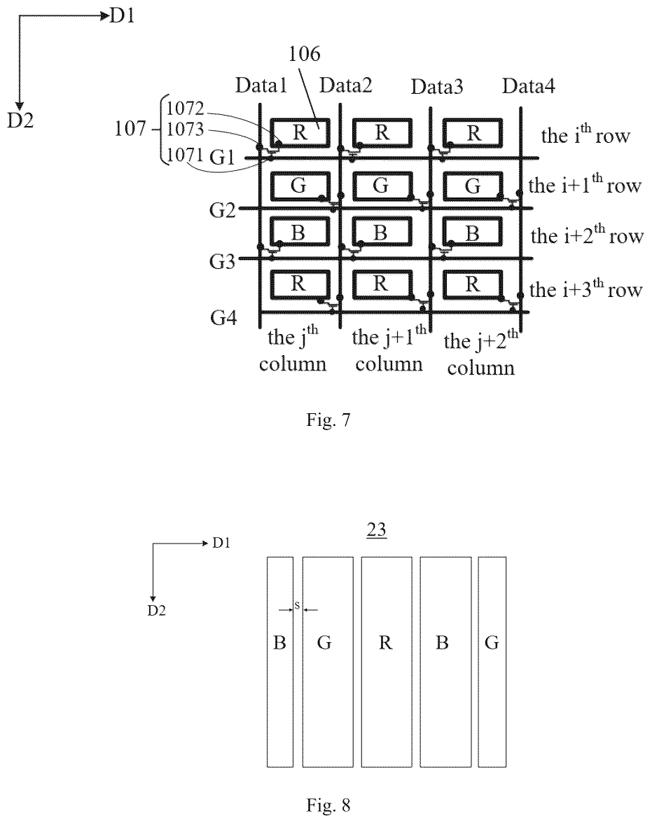

FIG. 7 shows an illustration of a part of the pixel structure of the display panel 100 according to an embodiment of the present disclosure. As shown in FIG. 7, a plurality of data lines and a plurality of gate lines intersect with each other to enclose a plurality of sub-pixels SP, and the ratio of the length L in the first direction D1 to the width W in the second direction D2 of each sub-pixel SP is 3:1. Each sub-pixel SP includes a pixel electrode 106 and at least one thin film transistor 107. The thin film transistor 107 includes a gate electrode 1071, a first electrode 1072, and a second electrode 1073. The first electrode 1072 may be a source electrode and the second electrode 1073 may be a drain electrode. Alternatively, the first electrode 1072 may be a drain electrode and the second electrode 1073 may be a source electrode. The gate electrode 1071 of the thin film transistor 107 of each sub-pixel SP is connected to the gate line, the first electrode 1072 of the thin film transistor 107 of each sub-pixel SP is connected to the pixel electrode 106 of the sub-pixel SP, the second electrode 1073 of the thin film transistor 107 of each sub-pixel SP is connected to the data line, and the second electrodes 1073 of the thin film transistors 107 of two adjacent sub-pixels in the same column of sub-pixels are connected to different data lines respectively. Specifically, FIG. 7 shows four rows by three columns of sub-pixels, and the sub-pixels in the same row emit the same color, for example, the sub-pixels in the i^{th} row emit red light, the sub-pixels in the i+1^{th} row emit green light, the sub-pixels in the i+2^{th} row emit blue light, and the sub-pixels in the i+3^{th} row emit red light. The pixel electrodes 106 in the i^{th} row sub-pixel are connected to the same gate line G1 via the gate electrodes 1071 of the thin film transistors 107, the pixel electrodes 106 in the i+1^{th} row sub-pixel are connected to the same gate line G2 via the gate electrodes 1071 of the thin film transistors 107, the pixel electrodes 106 in the i+2^{th} row sub-pixel are connected to the same gate line G3 via the gate electrodes 1071 of the thin film transistors 107, and the pixel electrodes 106 in the i+3^{th} row sub-pixel are connected to the same gate line G4 via the gate electrodes 1071 of the thin film transistors 107. The pixel electrode 106 in the sub-pixel located in the j^{th} column and i^{th} row is connected to the data line Data1 via the second electrode 1073 of the thin film transistor 107, while the pixel electrode 106 in the sub-pixel located in the j^{th} column and i+1^{th} row is connected to the data line Data2 via the second electrode 1073 of the thin film transistor 107; the pixel electrode 106 in the sub-pixel located in the j+1^{th} column and i^{th} row is connected to the data line Data2 via the second electrode 1073 of the thin film transistor 107, while the pixel electrode 106 in the sub-pixel located in the j+1^{th} column and i+1^{th} row is connected to the data line Data3 via the second electrode 1073 of the thin film transistor 107; the pixel electrode 106 in the sub-pixel located in the j+2^{th} column and i^{th} row is connected to the data line Data3 via the second electrode 1073 of the thin film transistor 107, while the pixel electrode 106 in the sub-pixel located in the j+2^{th} column and i+1^{th} row is connected to the data line Data4 via the second electrode 1073 of the thin film transistor 107. Other sub-pixels have similar arrangement, which will not be described here. That is to say, in the display panel 100, the pixel electrodes 106 of two adjacent sub-pixels in the same column of sub-pixels are connected to different data lines via the second electrodes 1073 of the thin film transistors 107, and this arrangement of the pixel structure is called Z-architecture. The polarity distribution of sub-pixels of the display panel with the Z-architecture is more uniform, and the picture quality is better, so there will be no vertical stripes when displaying the picture, which can improve the user's impression.

FIG. 8 shows a schematic plan view of a partial structure of a color filter 23 in the related art, which is applied to a conventional single gate display panel. As shown in FIG. 8, the color filter 23 includes a plurality of sub-color filters, namely, a red (R) sub-color filter, a green (G) sub-color filter, and a blue (B) sub-color filter. The length of each sub-filter in the first direction D1 is smaller than the width in the second direction D2. As shown in FIG. 8, there is a distance S between two adjacent sub-color filters, and the distance S is related to the width of the light shielding layer. The wider the width of the light shielding layer, the greater the distance S between two adjacent sub-color filters. With such design, a concave region is formed at the interval between two adjacent sub-color filters, the fluidity of the liquid crystal in the concave region deteriorates, resulting in the phenomenon of dark non-uniformity (DNU) in the display panel.

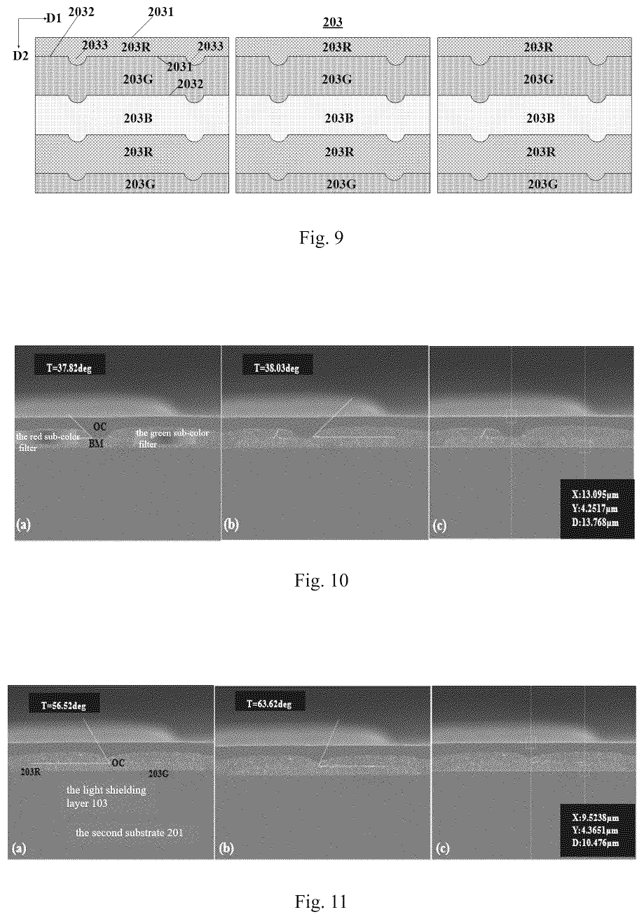

FIG. 9 shows a schematic plan view of a partial structure of a color filter 203 provided according to an embodiment of the present disclosure, and the display panel 100 may include the color filter 203. The light shielding layer 103 is arranged on the side of the second substrate 201 facing the first substrate 101, and the color filter 203 is arranged on the side of the light shielding layer 103 away from the second substrate 201. The color filter 203 includes a plurality of sub-color filters, for example, may include a red sub-color filter 203R, a green sub-color filter 203G, and a blue sub-color filter 203B. The length of each sub-color filter in the first direction D1 is greater than the width in the second direction D2. The plurality of sub-color filters are arranged in rows along the first direction D1 and columns along the second direction D2, and there is no gap between any two adjacent sub-color filters in the same column of sub-color filters, that is, there is zero gap between any two adjacent sub-color filters in the same column of sub-color filters. Through this design, it is possible to reduce or even avoid the formation of a concave region between two adjacent sub-color filters in the same column of sub-color filters, thereby improving the fluidity of liquid crystal and helping to improve the phenomenon of dark non-uniformity in the display panel 100.

As shown in FIG. 9, in some embodiments, each sub-color filter includes a seventh edge 2031 and an eighth edge 2032 extending in the first direction D1 and opposite to each other, the eighth edge 2032 of each sub-color filter is in direct contact with the seventh edge 2031 of another sub-color filter adjacent in the second direction D2, and the eighth edge 2032 includes at least one protrusion 2033. As an example, FIG. 9 shows that the eighth edge 2032 of each sub-color filter includes two protrusions 2033 protruding toward another sub-color filter adjacent in the second direction D2.

The photo spacer 202 is located at the side of the color filter 203 away from the second substrate 201, and the protrusion 2033 can be used to receive the base of the photo spacer 202, that is, the photo spacer 202 is disposed at the contact position of two adjacent sub-color filters in the second direction D2. Theoretically, the thickness of each sub-color filter of the color filter 203 should be the same, but in actual process, because sub-color filters with different colors are formed by different mask processes, it is difficult to achieve complete consistency in thickness for the sub-color filters, and there may be some differences in the thickness of two adjacent sub-color filters. If the sub-color filter is not provided with the protrusion 2033 at the eighth edge 2032, the base of the photo spacer 202 may be placed in an uneven position due to the different thicknesses of two adjacent sub-color filters, which is not beneficial to the stability of the photo spacer 202. In the embodiment of the present disclosure, the protrusion 2033 is designed at the eighth edge 2032 of the sub-color filter to accommodate the base of the photo spacer 202, because the protrusion 2033 is located at the eighth edge 2032 of the sub-color filter, the protrusion 2033 and the sub-color filter to which the protrusion 2033 belongs are prepared in the same mask process, so the thickness of the protrusion 2033 is the same as the thickness of the sub-color filter to which the protrusion 2033 belongs. The base of the photo spacer 202 is placed at the protrusion 2033, which can ensure that the photo spacer 202 is placed more smoothly and stably.

FIG. 10 shows a picture of a scanning electron microscope at the color filter 23 of a conventional display panel. FIG. 10 shows adjacent red and green sub-color filters of the color filter 23, a light shielding layer BM located at an interval region between the red and green sub-color filters, and an optical layer (OC). FIG. 10(a) shows the edge slope angle of the red sub color filter, which is about 37 degrees. FIG. 10(b) shows the edge slope angle of the green sub-color filter, which is about 38 degrees. FIG. 10(c) shows the total thickness Y of the color filter 23, the light shielding layer BM and the optical layer (OC), which is about 4.2517 μm.

FIG. 11 shows a picture of a scanning electron microscope at the color filter 203 of the display panel 100 according to an embodiment of the present disclosure. FIG. 11 shows the second substrate 201, the adjacent red sub-color filter 203R and the green sub-color filter 203G of the color filter 203, the light shielding layer 103, and an optical layer (OC). FIG. 11(a) shows the edge slope angle of the red sub-color filter 203R, which is about 56 degrees. FIG. 11(b) shows the edge slope angle of the green sub-color filter 203G, which is about 63 degrees. Compared with the color filter 23, the edge slope angle of the color filter 203 is larger. FIG. 11(c) shows the total thickness Y of the color filter 203, the light shielding layer 103 and the optical layer (OC), which is about 4.3651 μm. Compared with the conventional display panel, the total thickness Y of the color filter 203, the light shielding layer 103 and the optical layer (OC) of the display panel 100 is slightly larger, and the thickness difference is about 0.11 μm.

It should be pointed out that the embodiments or examples described above can be combined with each other to realize more embodiments or examples without contradiction.

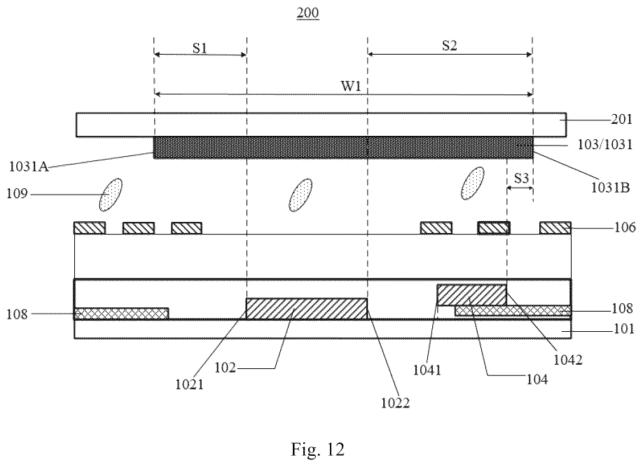

FIG. 12 shows a schematic sectional view of a partial structure of a display panel 200 according to another embodiment of the present disclosure. The display panel 200 has basically the same structure as the display panel 100, and therefore the same reference numerals are used to refer to the same components. The display panel 200 includes: a first substrate 101; a plurality of gate lines 102 arranged on the first substrate 101 and extending in a first direction D1; a plurality of common leads 104 arranged on the first substrate 101 and extending in the first direction D1; and a light shielding layer 103 located at a side of the gate line 102 away from the first substrate 101 and including a first part 1031 arranged in the first direction D1. Any one of the plurality of gate lines 102 and any one of the plurality of common leads 104 are adjacent to each other, and the orthographic projections of the adjacent gate line 102 and common lead 104 on the first substrate 101 fall within the orthographic projection of the first part 1031 of the light shielding layer 103 on the first substrate 101. The two edges of the gate line 102 extending in the first direction D1 include a first edge 1021 and a second edge 1022, and the two edges of the first part 1031 of the light shielding layer 103 extending in the first direction D1 include a third edge 1031A and a fourth edge 1031B. The first edge 1021 is farther away from the common lead 104 adjacent to the gate line 102 than the second edge 1022, and the first edge 1021 is closer to the third edge 1031A than the second edge 1022. The distance between the orthographic projection of the first edge 1021 on the first substrate 101 and the orthographic projection of the third edge 1031A on the first substrate 101 is a first distance S1, and the distance between the orthographic projection of the second edge 1022 on the first substrate 101 and the orthographic projection of the fourth edge 1031B on the first substrate 101 is a second distance S2. S1 and S2 may be the same or different. In some embodiments, S1 and S2 are 6~15 μm, such as 6 μm, 7 μm, 8 μm, 9 μm, 10 μm, 11 μm, 12 μm, 13 μm, 14 μm, 15 μm, etc. Near the gate line 102, especially near the first edge 1021 of the gate line 102, light leakage from the side view angle is easy to occur, and the light leakage distance is about 8~11 μm. By making the two edges 1031A and 1031B of the first part 1031 of the light shielding layer 103 extend beyond the two edges 1021 and 1022 of the gate line 102 by 6~15 μm, respectively, the light leakage region can be shielded, thereby avoiding the light leakage phenomenon from the side view angle.

In an example, S1 is 8.5 μm. The width W1 of the first part 1031 has a significant influence on the aperture ratio of the sub-pixel SP. Therefore, by making the third edge 1031A of the first part 1031 of the light shielding layer 103 extend beyond the first edge 1021 of the gate line 102 by about 8.5 μm, the width W1 of the first part 1031 is minimized on the premise of shielding the light leakage from the side view angle at the gate line 102, thereby maximizing the aperture ratio of the sub-pixel SP.

In some embodiments, the two edges of the common lead 104 extending in the first direction D1 include a fifth edge 1041 and a sixth edge 1042, the sixth edge 1042 is closer to the fourth edge 1031B of the first part 1031 of the light shielding layer 103 than the fifth edge 1041. The distance between the orthographic projection of the sixth edge 1042 on the first substrate 101 and the orthographic projection of the fourth edge 1031B on the first substrate 101 is a third distance S3, which is smaller than S1 and S2. In some examples, S3 is 2~4 μm, such as 2 μm, 3 μm, 4 μm. On the side of the common lead 104 far away from the adjacent gate line 102, there is a weak region of rubbing orientation (which is used to arrange the liquid crystal molecules according to rubbing orientation) where has poor anchoring of liquid crystal and is easy to cause light leakage from the side view angle. Generally, the range of the weak region of rubbing orientation is 2~4 μm. Therefore, by making the distance S3 that the first part 1031 of the light shielding layer 1031 extends beyond the common lead 104 be 2~4 μm, the risk of light leakage from the side view angle can be reduced or even avoided. In an example, S3 is 3 μm, which can minimize the width W1 of the first part 1031 on the premise of avoiding light leakage from the side view angle, thus maximizing the aperture ratio of the sub-pixel SP.

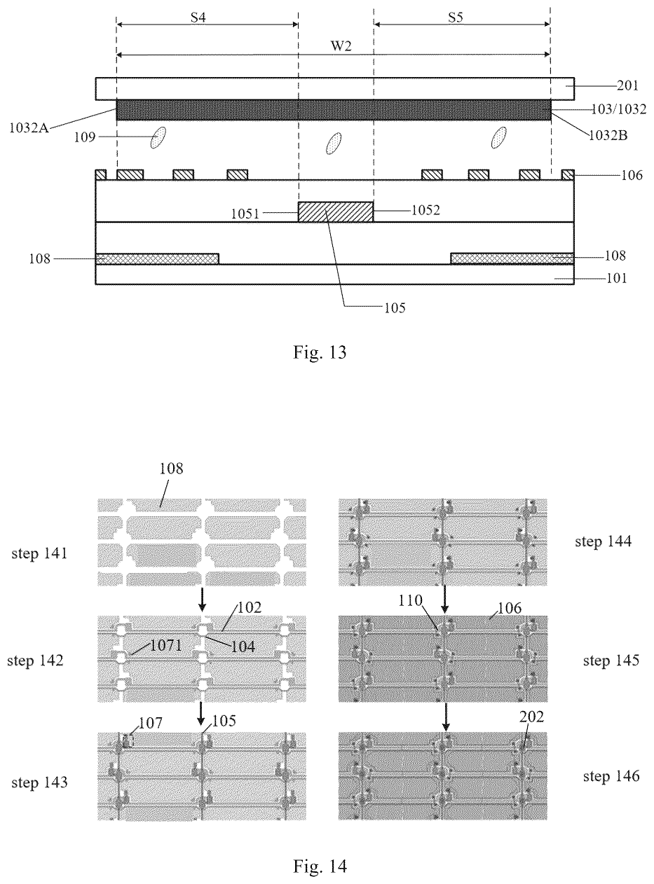

FIG. 13 shows a schematic sectional view of another partial structure of the display panel 200. As shown in FIG. 13, the display panel 200 may further include a plurality of data lines 105, which are arranged on the first substrate 101 and extend along a second direction D2, the second direction D2 intersecting with the first direction D1. The light shielding layer 103 further includes a second part 1032 arranged in the second direction D2. The orthographic projection of each data line 105 on the first substrate 101 falls within the orthographic projection of the second part 1032 of the light shielding layer 103 on the first substrate 101. Each data line 105 includes two edges 1051 and 1052 extending in the second direction D2, and the second part 1032 of the light shielding layer 103 includes two edges 1032A and 1032B extending in the second direction D2. The distance S4 between the orthographic projection of the edge 1051 of the data line 105 on the first substrate 101 and the orthographic projection of the edge 1032A of the second part 1032 of the light shielding layer 103 on the first substrate 101 is 13~30 μm, for example, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, etc. The distance S5 between the orthographic projection of the edge 1052 of the data line 105 on the first substrate 101 and the orthographic projection of the edge 1032B of the second part 1032 of the light shielding layer 103 on the first substrate 101 is 13~30 μm, for example, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, etc. Because the electric field between the data line 105 and the pixel electrode 106 causes the liquid crystal to rotate unexpectedly, the phenomenon of light leakage from side view angle is easy to occur near the data line 105. The second part 1032 of the light shielding layer 103 extends beyond two sides of the data line 105 by about 13~30 μm in the first direction D1, on one hand, it can shield the light leakage region (the width of the light leakage region is about 13 μm) to avoid light leakage from the side view angle, on the other hand, even if the array substrate and the counter substrate of the display panel 200 are misaligned (the alignment accuracy is about 6.5 μm) during assembly, the width W2 of the second part 1032 can ensure that there will be no light leakage due to the misalignment.

The plurality of data lines 105 and the plurality of gate lines 102 intersect with each other to enclose the plurality of sub-pixels SP, each sub-pixel SP has a length L along the first direction D1 and a width W along the second direction D2, the length L of each sub-pixel SP is greater than the width W. The first part 1031 of the light shielding layer 103 has a width W1 along the second direction D2, and the second part 1032 of the light shielding layer 103 has a width W2 along the first direction D1, and W1 is less than W2. The first part 1031 of the light shielding layer 103 is arranged along the long side direction of the sub-pixel SP, and the second part 1032 of the light shielding layer 103 is arranged along the short side direction of the sub-pixel SP. Therefore, for each sub-pixel SP, the area occupied by the first part 1031 of the light shielding layer 103 is larger than that occupied by the second part 1032, so that the width W1 of the first part 1031 has a greater influence on the aperture ratio of the sub-pixel SP. In the display panel 200, by making the width W1 of the first part 1031 of the light shielding layer 103 smaller than the width W2 of the second part 1032, the width W1 of the first part 1031 can be minimized on the premise of shielding the light leakage, so as to maximize the aperture ratio of the sub-pixel SP and promote the improvement of brightness of the display panel 200.

In some embodiments, the width W1 of the first part 1031 of the light shielding layer 103 is about 30.5 μm, and the width W2 of the second part 1032 of the light shielding layer 103 is about 57 μm.

FIG. 14 shows a structural diagram of a display panel in different preparation stages according to an embodiment of the present disclosure, the display panel may be the display panel 100 or the display panel 200 described in the previous embodiments. First, at step 141, the common electrode 108 is formed on the first substrate 101 by a first mask process, and the material of the common electrode 108 may be indium tin oxide. Then, at step 142, structures such as the gate line 102, the common lead 104 and the gate electrode 1071 of the thin film transistor 107 are formed on the side of the common electrode 108 away from the first substrate 101 by a second mask process, there is no insulating layer between the common lead 104 and the common electrode 108, and the common lead 104 and the common electrode 108 can be directly overlapped to realize electrical connection. Then, at step 143, the data line 105 and the first electrode 1072 and the second electrode 1073 of the thin film transistor 107 are formed by a third mask process on the side of the gate line 102 and the common lead 104 away from the first substrate 101. Then, at step 144, a passivation layer is formed on the side of the data line 105 away from the first substrate 101 by a fourth mask process. Then, at step 145, structures such as the pixel electrode 106 and the connecting line 110 are formed on the side of the passivation layer away from the first substrate 101 by a fifth mask process, and the materials of the pixel electrode 106 and the connecting line 110 may be indium tin oxide. By using five masks, the array substrate of the display panel can be prepared.

At step 146, a color film substrate of the display panel may be prepared through five mask processes. Specifically, the light shielding layer 103 may be first formed on the second substrate 201 through a mask process A; then, a sub-color filter 203R of the color filter 203 is formed on the side of the light shielding layer 103 away from the second substrate 201 through a mask process B; then, a sub-color filter 203G of the color filter 203 is formed on the side of the light shielding layer 103 away from the second substrate 201 through a mask process C; then, a sub-color filter 203B of the color filter 203 is formed on the side of the light shielding layer 103 away from the second substrate 201 through a mask process D; and then, a photo spacer 202 is formed on the side of the color filter 203 away from the second substrate 201 through a mask process E. FIG. 14 does not show the structures of the light shielding layer 103 and the color filter 203, and the specific structures of the light shielding layer 103 and the color filter 203 may be referred to the previous description about FIGS. 1 and 9. Step 146 may be executed in parallel with any of the previous steps 141-145, or before or after any of the previous steps 141-145, which is not specifically limited by the embodiment of the present disclosure. The array substrate prepared by steps 141-145 is assembled with the color film substrate prepared by step 146, so that the display panel 100 or 200 as described above can be obtained.

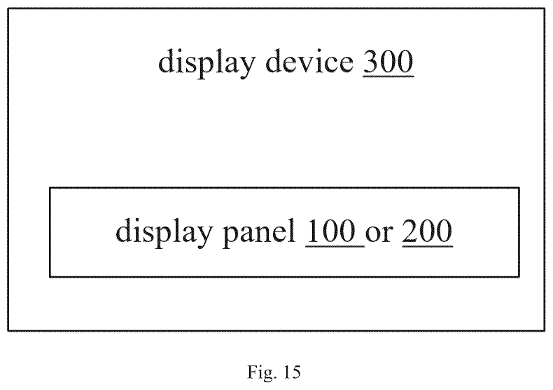

FIG. 15 shows a block diagram of a display device 300 according to an embodiment of the present disclosure, which may include the display panel 100 or 200 described in any of the previous embodiments. In some embodiments, the display device 300 may be a touch display device. The display device 300 includes but is not limited to any products or components with display function, such as a liquid crystal display, an electronic paper, a mobile phone, a tablet computer, a television, a notebook computer, a digital photo frame, a navigator, and the like.

The display device 300 may have basically the same technical effect as the display panel 100 or 200 described in the previous embodiments, and for the sake of brevity, the technical effect of the display device 300 is not repeated here.

It will be understood that although the terms first, second, third, etc. may be used herein to describe various elements, components, regions, layers and/or portions, these elements, components, regions, layers and/or portions should not be limited by these terms. These terms are only used to distinguish an element, component, region, layer or portion from another element, component, region, layer or portion. Thus, a first element, component, region, layer or portion discussed above could be termed a second element, component, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, components and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

Examples of different embodiments have been fully described above. These examples are not mutually exclusive, and features found in an example can be combined with features found in one or more other examples to achieve additional embodiments. Therefore, it will be understood that the examples shown in the figures are provided for illustration purposes only, and they are not intended to limit the disclosure in any way.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A display panel comprising:
a first substrate;
a plurality of gate lines on the first substrate and extending along a first direction;
a plurality of sub-pixels arranged in an array, each of the plurality of sub-pixels having a length along the first direction and a width along a second direction, the length of each sub-pixel being greater than the width of each sub-pixel, the second direction intersecting with the first direction; and
a light shielding layer on a side of the plurality of gate lines away from the first substrate and comprising a first part along the first direction and a second part along the second direction,
wherein a width of the first part along the second direction is less than a width of the second part along the first direction.

2. The display panel according to claim 1, wherein a ratio of the width to the length of each sub-pixel is 1:3.

3. The display panel according to claim 1, further comprising:
a plurality of common leads on the first substrate and extending along the first direction; and
a plurality of data lines on the first substrate and extending along the second direction, the plurality of data lines and the plurality of gate lines intersecting with each other to enclose the plurality of sub-pixels,
wherein each gate line is adjacent to a common lead, a gate line and a common lead that are adjacent are between two adjacent rows of sub-pixels, and orthographic projections of the gate line and the common lead that are adjacent on the first substrate fall within an orthographic projection of the first part of the light shielding layer on the first substrate.

4. The display panel according to claim 3, wherein,
two edges of the gate line extending along the first direction comprise a first edge and a second edge, two edges of the first part of the light shielding layer extending along the first direction comprise a third edge and a fourth edge, the first edge is farther away from the common lead adjacent to the gate line than the second edge, and the first edge is closer to the third edge than the second edge, and
a distance between an orthographic projection of the first edge on the first substrate and an orthographic projection of the third edge on the first substrate is a first distance, a distance between an orthographic projection of the second edge on the first substrate and an orthographic projection of the fourth edge on the first substrate is a second distance, the first distance is equal or unequal to the second distance.

5. The display panel according to claim 4, wherein the first distance and the second distance are both 6~15 μm.

6. (canceled)

7. The display panel according to claim 4, wherein two edges of the common lead extending along the first direction comprise a fifth edge and a sixth edge, the sixth edge is closer to the fourth edge than the fifth edge, a distance between an orthographic projection of the sixth edge on the first substrate and the orthographic projection of the fourth edge on the first substrate is a third distance, the third distance is less than the first distance and the second distance.

8. (canceled)

9. The display panel according to claim 3, wherein an orthographic projection of each of the plurality of data lines on the first substrate falls within an orthographic projection of the second part of the light shielding layer on the first substrate, and a distance between an orthographic projection of two edges extending along the second direction of each data line on the first substrate and an orthographic projection of two edges extending along the second direction of the second part of the light shielding layer on the first substrate is 13~30 μm.

10. The display panel according to claim 4, further comprising a plurality of pixel electrodes arranged in an array on the first substrate,
wherein each sub-pixel is provided with one of the plurality of pixel electrodes, each pixel electrode comprises a first side and a second side extending along the first direction and opposite to each other, an orthographic projection of the first side on the first substrate is between an orthographic projection of the common lead on the first substrate and an orthographic projection of the gate line adjacent to the common lead on the first substrate. and
wherein a distance between the orthographic projection of the first side of a pixel electrode of the plurality of pixel electrodes on the first substrate and the orthographic projection of the second edge of the gate line on the first substrate is a fourth distance. the fourth distance is less than or equal to the first distance and the second distance.

11. (canceled)

12. (canceled)

13. The display panel according to claim 10, further comprising a plurality of thin film transistors on the first substrate, each sub-pixel comprising at least one of the plurality of thin film transistors,
wherein a gate electrode of a thin film transistor of each sub-pixel is electrically connected with the gate line, a first electrode of the thin film transistor of each sub-pixel is electrically connected with the pixel electrode of the sub-pixel, a second electrode of the thin film transistor of each sub-pixel is electrically connected with a data line of the plurality of data lines, and the second electrodes of the thin film transistors of two adjacent sub-pixels in a same column of sub-pixels are electrically connected with different data lines respectively.

14. The display panel according to claim 10, further comprising a plurality of common electrodes arranged in an array on the first substrate, wherein each sub-pixel is provided with one of the plurality of common electrodes, each common electrode comprises a third side and a fourth side extending along the first direction and opposite to each other, two adjacent common electrodes in the second direction are at two sides of a same gate line, a distance between an orthographic projection of the third side of one of the two adjacent common electrodes on the first substrate and the orthographic projection of the first edge of the same gate line on the first substrate is a fifth distance, a distance between an orthographic projection of the fourth side of the other of the two adjacent common electrodes on the first substrate and the orthographic projection of the second edge of the same gate line on the first substrate is a sixth distance, both the fifth distance and the sixth distance are greater than or equal to the fourth distance.

15. (canceled)

16. (canceled)

17. (canceled)

18. The display panel according to claim 3, further comprising:
a second substrate opposite to the first substrate; and
a photo spacer between the first substrate and the second substrate,
wherein each of the plurality of data lines comprises a body part and a widening part, a width of the widening part along the first direction is greater than a width of the body part along the first direction, and an orthographic projection of the photo spacer on the first substrate falls within an orthographic projection of the widening part on the first substrate.

19. The display panel according to claim 18, further comprising:
a plurality of common electrodes on the first substrate, each sub-pixel comprising one of the plurality of common electrodes, and the common electrodes in a same row of sub-pixels being connected to a same common lead; and
a connecting line through which the common electrodes of two adjacent sub-pixels in a same column of sub-pixels are electrically connected to each other,
wherein in a thickness direction of the first substrate, the connecting line partially overlaps with the gate line and the common lead to form a first overlapping structure, the gate line partially overlaps with a data line of the plurality of data lines to form a second overlapping structure, the common lead partially overlaps with the data line to form a third overlapping structure, and a thin film transistor electrically connected with the gate line partially overlaps with the gate line to form a fourth overlapping structure; and
wherein orthographic projections of the first overlapping structure, the second overlapping structure, the third overlapping structure and the fourth overlapping structure on the first substrate surround the orthographic projection of the photo spacer on the first substrate.

20. The display panel according to claim 18, further comprising a color filter on a side of the second substrate facing the first substrate, wherein the color filter comprises a plurality of sub-color filters arranged in a plurality of rows along the first direction and in a plurality of columns along the second direction, and there is no gap between any two adjacent sub-color filters in a same column of sub-color filters.

21. The display panel according to claim 20,
wherein each sub-color filter comprises a seventh edge and an eighth edge extending along the first direction and opposite to each other, the eighth edge of each sub-color filter is in direct contact with the seventh edge of another sub-color filter adjacent in the second direction, and the eighth edge comprises at least one protrusion, and
wherein the photo spacer is at a side of the color filter away from the second substrate, and the protrusion is configured to accommodate a bottom of the photo spacer.

22. (canceled)

23. A display panel comprising:
a first substrate;
a plurality of gate lines on the first substrate and extending along a first direction;
a plurality of common leads on the first substrate and extending along the first direction; and
a light shielding layer on a side of the plurality of gate lines away from the first substrate and comprising a first part along the first direction,
wherein any one of the plurality of gate lines and any one of the plurality of common leads are adjacent to each other, and orthographic projections of a gate line and a common lead that ate adjacent on the first substrate fall within an orthographic projection of the first part of the light shielding layer on the first substrate, and
wherein two edges of the gate line extending along the first direction comprise a first edge and a second edge, two edges of the first part of the light shielding layer extending along the first direction comprise a third edge and a fourth edge, the first edge is farther away from the common lead adjacent to the gate line than the second edge, and the first edge is closer to the third edge than the second edge, a distance between an orthographic projection of the first edge on the first substrate and an orthographic projection of the third edge on the first substrate is a first distance, a distance between an orthographic projection of the second edge on the first substrate and an orthographic projection of the fourth edge on the first substrate is a second distance, the first distance is equal or unequal to the second distance.

24. The display panel according to claim 23, wherein the first distance and the second distance are both 6~15 μm.

25. The display panel according to claim 23, wherein two edges of the common lead extending along the first direction comprise a fifth edge and a sixth edge, the sixth edge is closer to the fourth edge than the fifth edge, a distance between an orthographic projection of the sixth edge on the first substrate and the orthographic projection of the fourth edge on the first substrate is a third distance, the third distance is less than the first distance and the second distance.

26. (canceled)

27. The display panel according to claim 23, further comprising a plurality of data lines on the first substrate and extending along a second direction, the second direction intersecting with the first direction,
wherein the light shielding layer further comprises a second part along the second direction, an orthographic projection of each of the plurality of data lines on the first substrate falls within an orthographic projection of the second part of the light shielding layer on the first substrate, and a distance between an orthographic projection of two edges extending along the second direction of each data line on the first substrate and an orthographic projection of two edges extending along the second direction of the second part of the light shielding layer on the first substrate is 13~30 μm.

28. The display panel according to claim 27, further comprising a plurality of sub-pixels arranged in an array, wherein each of the plurality of sub-pixels has a length along the first direction and a width along the second direction, the length of each sub-pixel is greater than the width of each sub-pixel, and a width of the first part of the light shielding layer along the second direction is less than a width of the second part of the light shielding layer along the first direction.

29. A display device comprising the display panel according to claim 1.
